(19) United States
(12) Patent Application Publication
(10) Pub. No.: US 2010/0109639 A1
(43) Pub. Date: May 6, 2010

(54) FREQUENCY SPECTRUM ANALYSIS SYSTEM AND METHOD

(75) Inventors: SHEN-AN CHEN, Tu-Cheng (TW); YOU-REN LIN, Tu-Cheng (TW); RONG-CONG HUNG, Tu-Cheng (TW); SHIH-CHANG CHEN, Tu-Cheng (TW); RONG-HWANG HORNG, Tu-Cheng (TW); YAW-SHEN LAI, Tu-Cheng (TW)

Correspondence Address: PCE INDUSTRY, INC.;ATT. Steven Reiss, 288 SOUTH MAYO AVENUE, CITY OF INDUSTRY, CA, 91789, US

(73) Assignee: FOXNUM TECHNOLOGY CO., LTD., Tucheng City (TW)

(21) Appl. No.: 12/334,543

(22) Filed: Dec. 15, 2008

(30) Foreign Application Priority Data
Oct. 31, 2008 (CN) 200810305333.X

(51) Int. Cl. G01R 23/16

(52) U.S. Cl. 324/76.21

(57) ABSTRACT

A frequency spectrum analysis system includes a control platform, a driver, and a controlled system. The control platform includes a first transmission device. The driver includes a second transmission device, a signal source, and a data logger. The first transmission device is connected to the second transmission device. The second transmission device is connected to the signal source. The signal source is connected to the data logger and the controlled system. The data logger is connected to the controlled system and the first transmission device.

### BACKGROUND

1. Technical Field

The present disclosure relates to analysis systems and methods, and particularly to a frequency spectrum analysis system and method.

2. Description of the Related Art

In the machining field, machining performances of a servo system not only depend on driver, motor, and characteristics of the servo system itself, but also optimum control parameters of the machine. It is important to get the optimum control parameters for the servo system working according to different machining conditions. When the servo system has optimum control parameters, the frequency range of the output signal of the servo system is greatest when the servo system is stable. The greatest frequency range is taken as a desired frequency bandwidth. Generally, a simulation module of the servo system is employed for a frequency spectrum analysis to determine the optimum control parameters. However, this method is not as precise as desired in practice.

### BRIEF DESCRIPTION OF THE DRAWINGS

FIG. 1 is a block diagram of an exemplary embodiment of a frequency spectrum analysis system including a servo system.

FIG. 2 is a flowchart of an exemplary embodiment of a frequency spectrum analysis method.

FIG. 3 shows exemplary waveform graphs of a speed input signal and a speed output signal in time domain of a speed control loop of the servo system in FIG. 1.

FIG. 4 is an exemplary magnitude-frequency characteristic curve of the speed input signal and the speed output signal in FIG. 3.

FIG. 5 shows exemplary waveform graphs of a current input signal and a current output signal in time domain of a current control loop of the servo system in FIG. 1.

FIG. 6 is an exemplary magnitude-frequency characteristic curve of the current input signal and the current output signal in FIG. 5.

### DETAILED DESCRIPTION

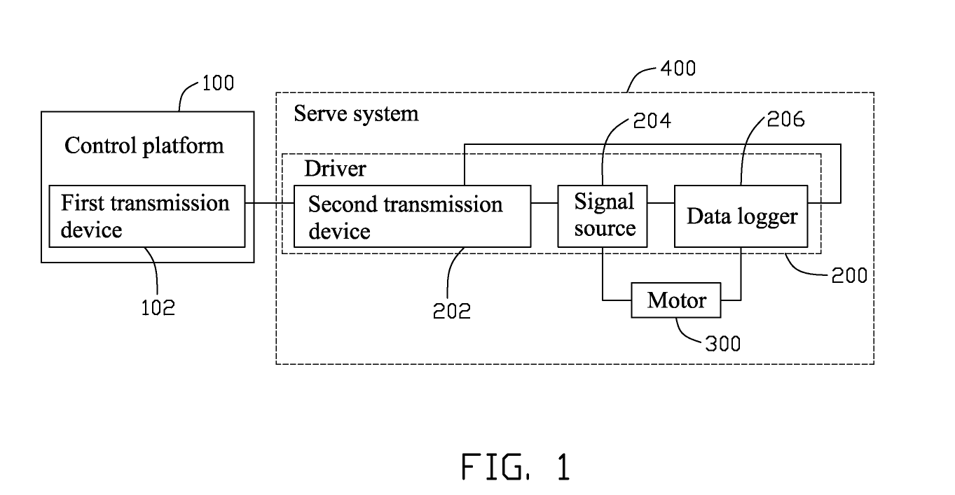

Referring to FIG. 1, an exemplary embodiment of a frequency spectrum analysis system 10 includes a control platform 100, such as a personal computer, and a servo system 400. The servo system 400 includes a driver 200 and a motor 300. In one exemplary embodiment, a proportional-integral (PI) plus function acting as a control parameter of a control loop of the servo system 400 is adjusted to obtain a frequency bandwidth of the control loop. Hereinafter, a speed control loop and a current control loop of the servo system 400 will be used as examples.

The control platform 100 includes a first transmission device 102, such an such as an RS-232 interface, an RS-485 interface and so on The driver 200 includes a second transmission device 202, a signal source 204, and a data logger 206. The first transmission device 102 of the control platform 100 is connected to the second transmission device 202 of the driver 200. The second transmission device 202, such as an RS-232 interface, an RS-485 interface and so on, is connected to the signal source 204. The signal source 204 is connected to the data logger 206 and the motor 300. The data logger 206 is connected to the motor 300 and the second transmission 202. The signal source 204 is capable of providing different frequencies, such as a chirp source (e.g., a short, sharp frequency source) for example, but the disclosure is not limited thereto. In one exemplary embodiment, the attenuation value of output signals of the motor 300, functioning as output signals of the servo system, is −3 dB. That is to say, the output signal divided by the input signal is 0.707, and the logarithm of 0.707 multiplied by 20 dB is −3 dB. When an output signal is 0.707 times an input signal of the motor 300, the frequency bandwidth of a control loop of the servo system 400 can be obtained by adjusting the PI plus of the control loop if the servo system 400 is stable.

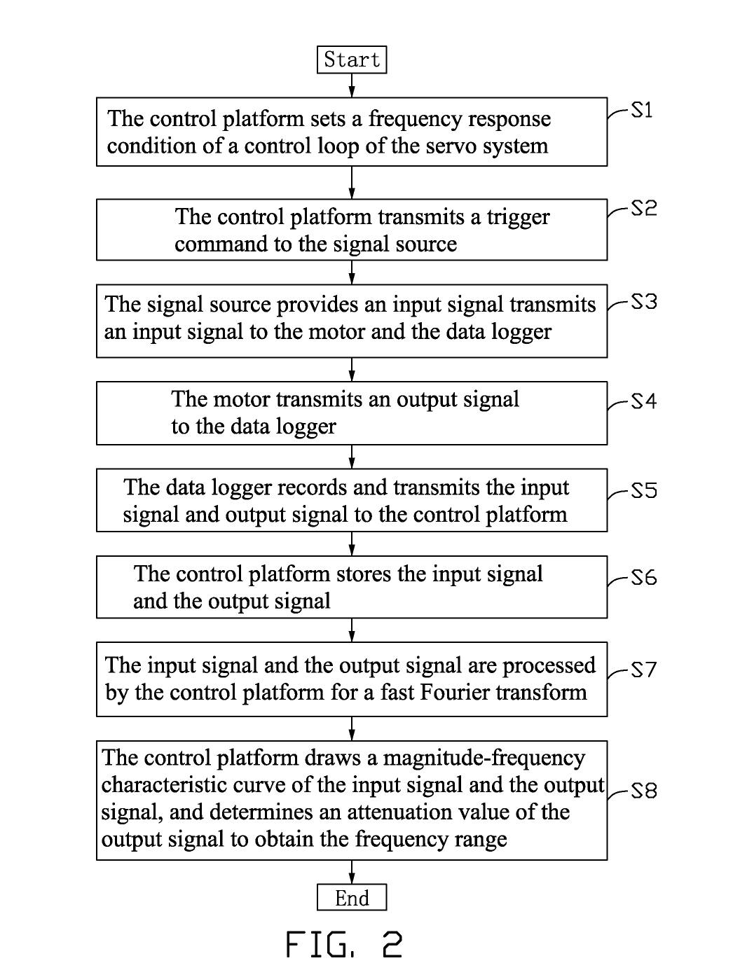

Referring to FIG. 2, one embodiment of a method of frequency spectrum analysis method for the servo system 400 is provided, which includes the following blocks. Depending on the embodiment, certain blocks described below may be removed, others may be added, and the sequence of the blocks may be altered.

In block S1, the control platform 100 sets a frequency response condition of a control loop of the servo system 400, such as an offset value, a magnitude value, and a sampling time of the input signal of the control loop of the servo system 400.

In block S2, the control platform 100 transmits a trigger command to the signal source 204 via the first transmission device 102 and the second transmission device 202 to trigger the signal source 204.

In block S3, the signal source 204, according to the trigger command, provides a frequency response trigger signal as the input signal of the control loop of the servo system 400, and transmits the input signal to the motor 300 and the data logger 206.

In block S4, the motor 300 outputs an output signal according to the input signal, and the output signal of the motor 300 functioning as an output signal of the servo system 400 is transmitted to the data logger 206.

In block S5, the data logger 206 records the input signal and output signal of the motor 300, and transmits the input signal and output signal of the motor 300 to the control platform 100.

In block S6, the control platform 100 stores the input signal and the output signal of the motor 300 in a memory (not shown).

In block S7, the input signal and the output signal of the motor 300 are processed by the control platform 100 by processing the input signal and the output signal using a fast Fourier transform.

In block S8, the control platform 100 draws a magnitude-frequency characteristic curve of the input signal and the output signal of the motor 300 using the fast Fourier transform, and determines an attenuation value of the output signal thereby to obtain the frequency range of the output signal of the servo system 400.

Then, a determination is made whether the frequency range is the frequency bandwidth according to state performance of the servo system 400. The state performance of the servo system 400 may be according to steady state performance of the servo system 400, and the PI plus of the control loop of the servo system 400 can be adjusted as needed. In one embodiment, the determination may be done by an operator of the servo system 400. Hereinafter, the speed control loop and the current control loop of the servo system 400 are used to provide a detailed explanation about the frequency spectrum analysis system 10 and the method for the same.

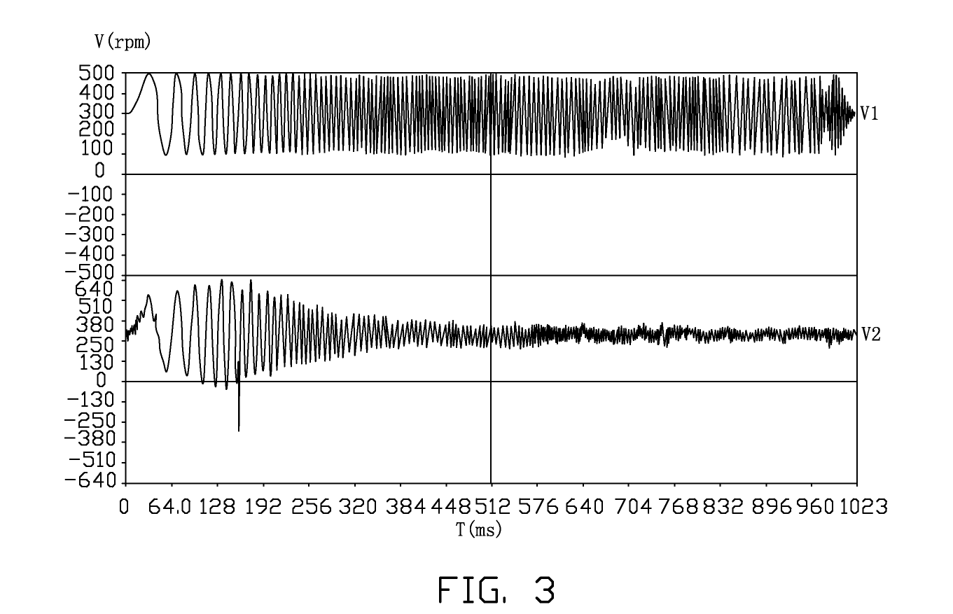

FIG. 3 illustrates exemplary waveform graphs of a speed input signal and a speed output signal in the time domain of the speed control loop of the servo system 400. Further details of the speed input signal and the speed output signal will be explained in further detail below. In the illustrated embodiment of FIG. 3, a frequency response condition of the speed control loop is set as: speed offset value S1=300 rpm, speed magnitude value M1=200 rpm, and sampling time t1=1 ms. The signal source 204 provides an input signal V1 for the motor 300 after the frequency response condition of the speed control loop is set by the control platform 100. The motor 300 outputs a corresponding speed output signal V2 after receiving the speed input signal V1.

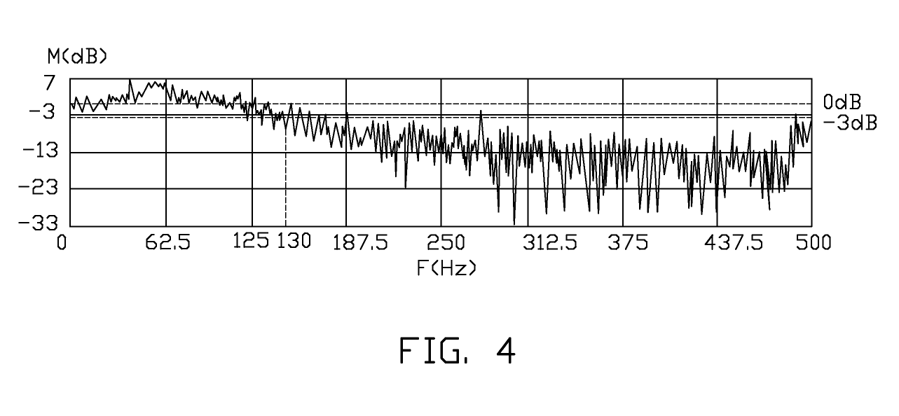

The control platform 100 stores the speed input signal V1 and the speed output signal V2 in the memory, and processes the speed input signal V1 and the speed output signal V2 using the fast Fourier transform for transforming the speed input signal V1 and the speed output signal V2 from the time domain to the frequency domain. Then, the control platform 100 draws a magnitude-frequency characteristic curve of the speed input signal V1 and the speed output signal V2 as shown in FIG. 4. It can be seen in FIG. 4 that the frequency range of the speed output signal V2 of the speed control loop of the servo system 400 is 130 Hz when the attenuation value of the speed output signal V2 is 3 dB.

If the servo system 400 is determined to be stable, that is to say, noise and vibration of the motor 300 are in a permitted range, the frequency range may be less than the frequency bandwidth. Therefore, the frequency range of the speed control loop of the servo system 400 can be increased by increasing the PI plus of the speed control loop so as to obtain the frequency bandwidth. However, the servo system 400 may become unstable when the PI plus of the speed control loop is increased to a certain value. When the servo system 400 is unstable, that is to say, the noise and the vibration of the motor 300 exceed the permitted range, the frequency range may be more than the frequency bandwidth. Therefore, the frequency range can be decreased by reducing the PI plus of the speed control loop so as to obtain the frequency bandwidth. When the frequency bandwidth is determined, the PI plus, functioning as a control parameter of the speed control loop of the servo system 400, is determined.

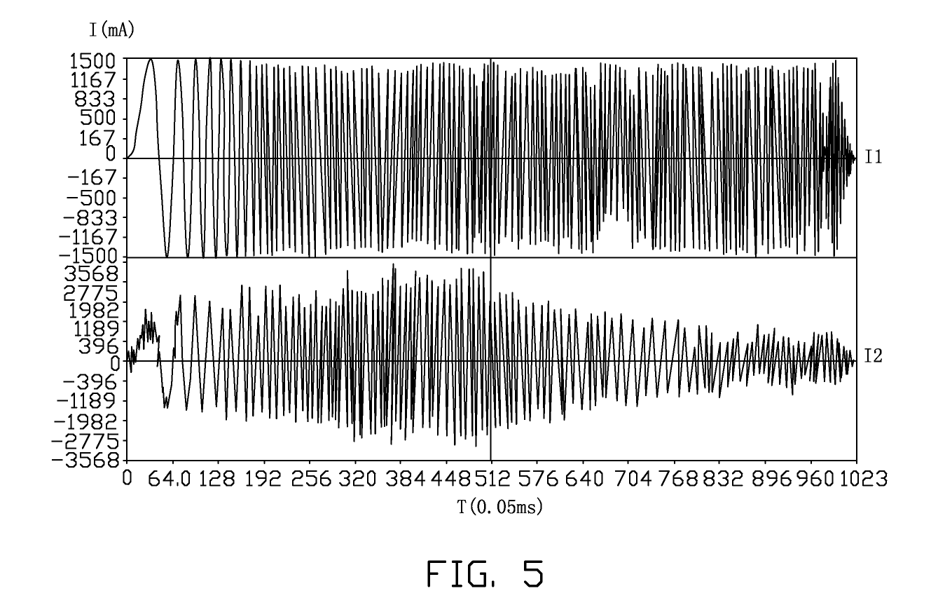

FIG. 5 illustrates exemplary waveform graphs of a current input signal and a current output signal in the time domain of the current control loop of the servo system 400. Further details of the current input signal and the current output signal will be explained in further detail below. In the illustrated embodiment of FIG. 5, a frequency response condition of the current control loop is set as: current offset value S2=0 mA, current magnitude value M2=1500 mA, sampling time t2=0.05 ms. The signal source 204 provides an input signal I1 for the motor 300 after the frequency response condition of the current control loop set by the control platform 100. The motor 300 outputs a corresponding current output signal I2 after receiving the current input signal I1.

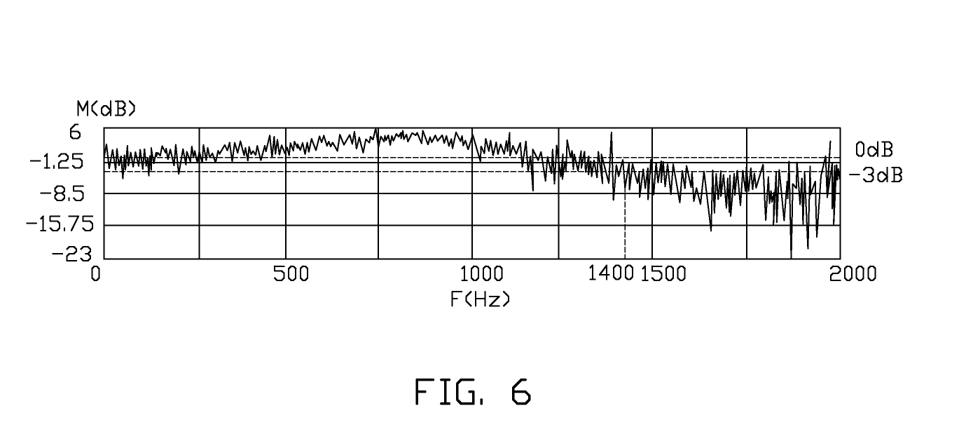

The control platform 100 stores the current input signal I1 and the current output signal I2 in the memory, and processes the current input signal I1 and the current output signal I2 by the fast Fourier transform for transforming the current input signal I1 and the current output signal I2 from the time domain to the frequency domain. Then the control platform 100 draws a magnitude-frequency characteristic curve of the current input signal I1 and the current output signal I2 as shown in FIG. 6. It can be seen in FIG. 6 that the frequency range of the current output signal I2 of the current control loop of the servo system 400 is 1400 Hz when the attenuation value of the current output signal I2 is 3 dB.

If the servo system 400 is determined to be stable, that is to say, noise and vibration of the motor 300 are in a permitted range, the frequency range of the current control loop of the servo system 400 may be less than the frequency bandwidth. Therefore, the frequency range can be increased by increasing the PI plus of the current control loop so as to obtain the frequency bandwidth. However, the servo system 400 may become unstable when the PI plus of the current control loop is increased to a certain value. When the servo system 400 is unstable, that is to say, the noise and the vibration of the motor 300 exceed the permitted range, the frequency range may be more than the frequency bandwidth. Therefore, the frequency range can be decreased by reducing the PI plus of the current control loop so as to obtain the frequency bandwidth. When the frequency bandwidth is determined, the PI plus functioning as a control parameter of the current control loop of the servo system 400, is determined.

In one exemplary embodiment, the control parameters such as PI plus values of other control loops of the servo system 400, such as a pressure control loop of the servo system 400, can be determined by using the frequency spectrum analysis system and method mentioned above. The selection of attenuation value of 3 dB can be other values.

It is to be understood, however, that even though numerous characteristics and advantages of the present disclosure have been set forth in the foregoing description, together with details of the structure and function of the disclosure, the disclosure is illustrative only, and changes may be made in detail, especially in matters of shape, size, and arrangement of parts within the principles of the disclosure to the full extent indicated by the broad general meaning of the terms in which the appended claims are expressed.

What is claimed is:

1. A system for analyzing frequency spectrums, the system comprising:
a control platform comprising a first transmission device and configured for providing a trigger command and;
a servo system comprising:
a motor; and
a driver configured for driving the motor, comprising:
a second transmission device connected to the first transmission device;
a signal source connected the second transmission device and the motor, and configured for receiving the trigger command via the first transmission device and the second transmission device, and providing an input signal of a control loop of the servo system to output an output signal from the motor for a frequency spectrum analysis of the servo system; and
a data logger connected to the signal source, the second transmission device and the motor, and configured for recording the input signal and the output signal of the motor and transmitting the input signal and the output signal to the control platform;
wherein the control platform transforms the input signal and the output signal of the motor from the time domain to the frequency domain and obtains the magnitude-frequency characteristic relationship of the input signal and the output signal, and determines an attenuation value of the output signal so as to obtain a frequency range of the output signal.

2. The system of claim 1, wherein the control platform transforms the input signal and the output signal from the time domain to the frequency domain using a fast Fourier transform.

3. The system of claim 1, wherein the control loop of the servo system is a current control loop of the servo system.

4. The system of claim 1, wherein the control loop of the servo system is a speed control loop of the servo system.

5. The system of claim 1, wherein the control loop of the servo system is a pressure control loop of the servo system.

6. The system of claim 1, wherein the attenuation value of the output signal of the servo system is 3 dB.

7. The system of claim 1, wherein the signal source is a chirp source.

8. The system of claim 1, wherein the control platform is a personal computer.

9. A method for analyzing frequency spectrums, comprising:
setting a frequency response condition of a control loop of a servo system by a control platform, wherein the servo system comprises a driver and a motor;
transmitting a trigger command by the control platform to a signal source located in the driver via a first transmission device of the control platform and a second transmission device of the driver;
providing an input signal by the signal source for the motor and transmitting the input signal to a data logger located in the driver;
outputting an output signal by the motor, recording the input signal and the output signal of the motor by the data logger, and transmitting the input signal and the output signal to the control platform;
storing the input signal and the output signal of the motor by the control platform from the data logger;
transforming the input signal and the output signal of the motor by the control platform from the time domain to the frequency domain; and
processing the input signal and the output signal of the motor by the control platform to obtain a magnitude-frequency characteristic relationship of the input signal and output signal, and determining an attenuation value of the output signal to obtain a frequency range of the output signal of the control loop of the servo system.

10. The method of claim 9, wherein the control platform transforms the input signal and the output signal from the time domain to the frequency domain using a fast Fourier transform.

11. The method of claim 9, wherein the control loop of the servo system is a current control loop of the servo system.

12. The method of claim 9, wherein the control loop of the servo system is a speed control loop of the servo system.

13. The method of claim 9, wherein the control loop of the servo system is a pressure control loop of the servo system.

14. The method of claim 9, wherein the attenuation value of the output signal of the servo system is 3 dB.

15. The method of claim 9, wherein the signal source is a chirp source.

16. The method of claim 9, wherein the control platform is a personal computer.
